(19) United States
(12) Patent Application Publication
(10) Pub. No.: US 2017/0287549 A1
(43) Pub. Date: Oct. 5, 2017

(54) SEMICONDUCTOR DEVICE SCHEME FOR ENSURING RELIABILITY BY PERFORMING REFRESH DURING ACTIVE OPERATION

(71) Applicant: SK hynix Inc., Icheon-si (KR)

(72) Inventors: Jae In LEE, Icheon-si Gyeonggi-do (KR); Sang Muk OH, Icheon-si Gyeonggi-do (KR)

(21) Appl. No.: 15/258,231

(22) Filed: Sep. 7, 2016

(30) Foreign Application Priority Data
Mar. 30, 2016 (KR) 10-2016-0038509

(51) Int. Cl. G11C 11/406; G11C 11/4096; G11C 11/4091

(52) U.S. Cl. CPC G11C 11/40618; G11C 11/4091; G11C 11/4096

(57) ABSTRACT

A semiconductor device and a system may be provided. The semiconductor device may include a plurality of memory cell groups. An active operation may be performed in one or more of the plurality of memory cell groups in correspondence to a real active signal. A refresh operation may be performed in one or more of other memory cell groups in correspondence to a pseudo active signal.

### CROSS-REFERENCES TO RELATED APPLICATION

The present application claims priority under 35 U.S.C. §119(a) to Korean application number 10-2016-0038509, filed on Mar. 30, 2016, in the Korean Intellectual Property Office, which is incorporated herein by reference in its entirety.

### BACKGROUND

### 1. Technical Field

Various embodiments may generally relate to a semiconductor device, and more particularly, to a semiconductor device relating to refresh efficiency.

### 2. Related Art

In a semiconductor device, a memory cell implements a capacitor for storing data. Accordingly, when a specific word line (WL) is selected, a transistor coupled to the word line is turned on, so that a voltage of a cell corresponding to the word line is outputted to a bit line (BL).

Through the passage of time the voltage of such a memory cell is gradually reduced. That is, as time passes a capacitor used as a memory cell in the semiconductor device discharges its own charge, and thus data is lost. This is a critical demerit in a memory device used to read and write data. Accordingly, in order to ensure the reliability of data, all devices using a semiconductor device should perform a refresh operation that recovers the charge of a memory cell.

When the size (area) of a capacitor is large, its capacitance also increases in proportional to the size, resulting in an increase in its discharge time. Conventionally, since the size of the capacitor is sufficiently large, the discharge of the memory cell does not easily occur and thus demands for data reliability are small.

However, with the recent miniaturization of a technology, since the size of a memory cell is reduced, it is not possible to ensure reliability. That is, as the size of a capacitor is reduced, data with a small capacity is stored and thus the capacitor is discharged in a short time as compared with the related art, resulting in a reduction of reliability.

### SUMMARY

In an embodiment, a semiconductor device may be provided. The semiconductor device may include a plurality of memory cell groups. An active operation may be performed in one or more of the plurality of memory cell groups in correspondence to a real active signal. A refresh operation may be performed in one or more of other memory cell groups in correspondence to a pseudo active signal.

### BRIEF DESCRIPTION OF THE DRAWINGS

FIG. 1 is a diagram illustrating a representation of an example of a structure of a semiconductor device according to an embodiment.

FIG. 2 is a diagram illustrating a representation of an example of the flow of signals of an embodiment of a semiconductor device of FIG. 1.

FIG. 3 is a diagram illustrating a representation of an example of a structure of a matrix (MAT) and a sense amplifier (SA) according to an embodiment.

FIG. 4 is a diagram illustrating a representation of an example of a structure of a memory cell according to an embodiment.

FIG. 5 is a circuit diagram of a representation of an example of a semiconductor device using a memory cell structure of FIG. 4.

FIG. 6 is a circuit diagram of a representation of an example of a input/output terminal of a semiconductor device according to an embodiment.

FIG. 7 illustrates a block diagram of an example of a representation of a system employing a semiconductor device with the various embodiments discussed above with relation to FIGS. 1-6.

### DETAILED DESCRIPTION

Hereinafter, a detailed embodiment will be described below with reference to the accompanying drawings.

Various embodiments may be directed to a semiconductor device scheme for ensuring reliability by performing a refresh by itself while in an active operation.

According to an embodiment, a configuration capable of refreshing a memory cell even in an active operation may be provided, so that refresh efficiency may be improved while reducing the reduction of memory performance and thus it may be possible to ensure reliability.

According to an embodiment, a memory cell may be divided into a plurality of memory cell groups such that a sense amplifier is not shared and refresh may be performed only for a memory cell to which an active signal is not inputted, so that data may not be lost.

According to an embodiment, only a memory cell group including an address inputted in an active operation may be activated and the other memory cell groups may be deactivated, so that data input/output may be possible for only a memory cell corresponding to the inputted address.

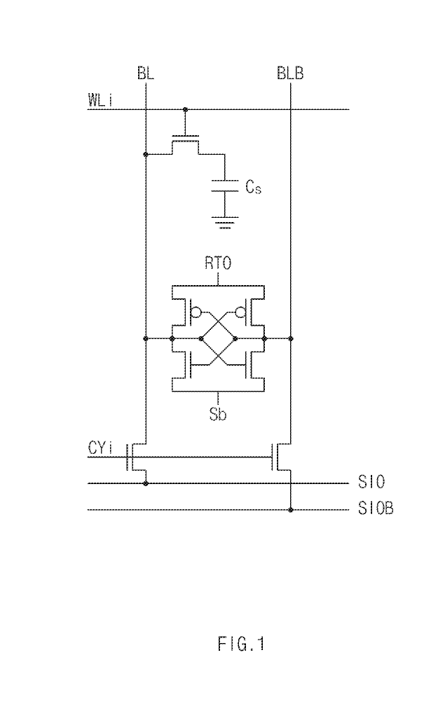

FIG. 1 is a diagram illustrating a representation of an example of a structure of a semiconductor device according to an embodiment. Referring to FIG. 1, a bit line bar line BLB, segment input/output bar line SIOB, signal RTO, and signal Sb are illustrated.

Referring to FIG. 1, a memory cell Cs implemented with, for example, a capacitor is coupled to a word line WLi and a bit line BL through a transistor. A sense amplifier is coupled to the bit line BL and is also coupled to a segment input/output line SIO through a column enable transistor CYi.

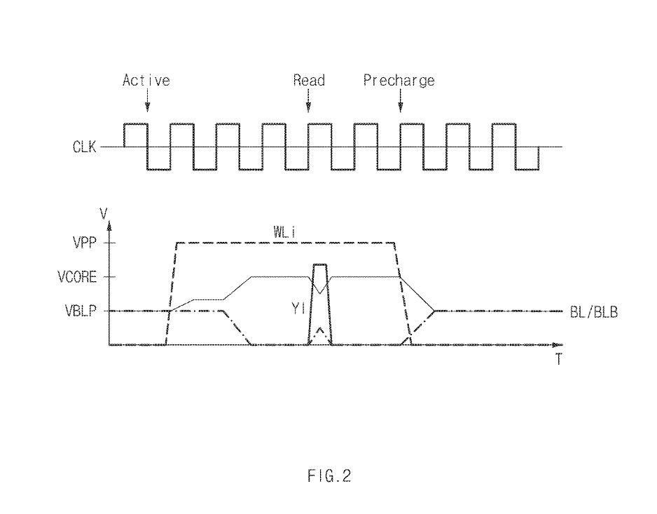

FIG. 2 illustrates voltages of each signal line according to input signals in a semiconductor device having a structure of FIG. 1.

Referring to FIG. 2, in the upper figure of FIG. 2 illustrating a clock signal CLK, an active signal Active is applied to the word line WLi as an input signal, and then a read signal Read is applied in order to output a signal of the bit line BL after a predetermined time. Then, a precharge signal Precharge is applied.

Referring now to the lower figure of FIG. 2, the y-axis is voltage V and the x-axis is time T. As the active signal is applied to the word line WLi, the word line WLi is boosted to a level VPP. Accordingly, the transistor coupled to the memory cell is enabled, so that the voltage of the memory cell is transferred to the sense amplifier. The sense amplifier amplifies the transferred voltage of the memory cell. For example, as illustrated in FIG. 2, the bit line BL and bit line bar line BLB are boosted to a level VCORE. At this time, when the read signal is applied, the column enable transistor CYi is enabled, so that the voltage of the bit line BL is transferred to the segment input/output line SIO. Then, as the precharge signal is applied, the word line WLi is disabled, that is, reaches a ground voltage and the voltage of the bit line BL reaches a precharge voltage VBLP.

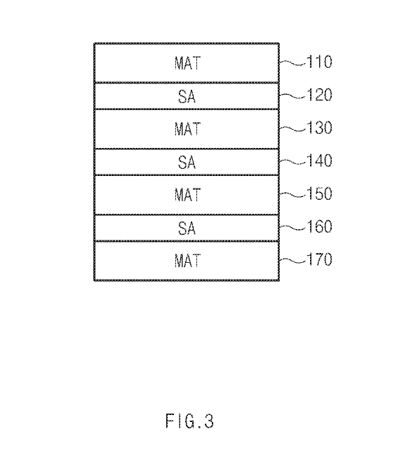

FIG. 3 is a diagram illustrating a representation of an example of a structure of a matrix (MAT) and a sense amplifier (SA) according to an embodiment. Referring to FIG. 3, sense amplifiers SA 120, 140, and 160 and matrixes MAT 110, 130, 150, and 170 are illustrated.

The matrix (MAT) indicates a unit in which memory cells storing data have been arranged in a matrix shape in a semiconductor device. The sense amplifier (SA) performs a function of amplifying the voltage of a bit line as described above. That is, the sense amplifier (SA) amplifies the voltage of a memory cell transferred to the bit line in a read operation, and amplifies an input voltage transferred to the bit line from an input/output line in a write operation. An example of a detailed operation of such a sense amplifier (SA) is as follows.

In a semiconductor device having, for example, the structure of FIG. 3, a SA 120 is positioned between a MAT 110 and a MAT 130 and amplifies a voltage difference between a bit line of the MAT 110 and a bit line (a bit line bar line) of the MAT 130 corresponding to the bit line of the MAT 110. For example, in the case of reading data for a specific word line in the MAT 110, an active signal is inputted to the MAT 110 and thus the specific word line is enabled, but the active signal is not applied to the other MATs 130, 150, and 170. Accordingly, a data value (for example, “+1”) of a memory cell corresponding to the specific word line is outputted from the MAT 110 to a bit line (hereinafter, referred to as a bit line 110) coupled to the MAT 110. At this time, since the MAT 130 has been deactivated, a reference voltage, for example, “0”, is outputted to a bit line (hereinafter, referred to as a bit line 130) coupled to the MAT 130. The SA 120 amplifies a difference between an output value of the bit line 110 and an output value of the bit line bar line 130, that is, “+1”, and outputs the amplified value to a data input/output line.

In the case of refreshing the MAT 130 by using the SA 120 operating in such a manner in the state in which the active signal has been applied to the MAT 110, an error may occur in data.

For example, in the case of reading data for a specific word line in the MAT 110, the active signal is inputted to the MAT 110, so that the specific word line is enabled. Accordingly, the data value “+1” is outputted to the bit line coupled to the MAT 110 from the SA 120. In order to refresh the MAT 130, the active signal is inputted to the MAT 130. Accordingly, the data value of to the MAT 110 may be outputted to the bit line bar line coupled to the MAT 130 from the SA 120. For example, when “+1” is outputted to the bit line bar line, the SA 120 amplifies a difference between “+1” outputted from the bit line 110 and “+1” outputted from the bit line bar line 130, that is, “0”, and outputs the amplified value to the data input/output line. “+1” has been stored in the MAT 110 but there occurs an error that “0” is outputted.

Consequently, in the present embodiment, even when the active signal is applied to any memory cell, refresh is performed for the memory cell and a memory cell not sharing a sense amplifier, so that memory performance is improved and a data error is substantially prevented from occurring.

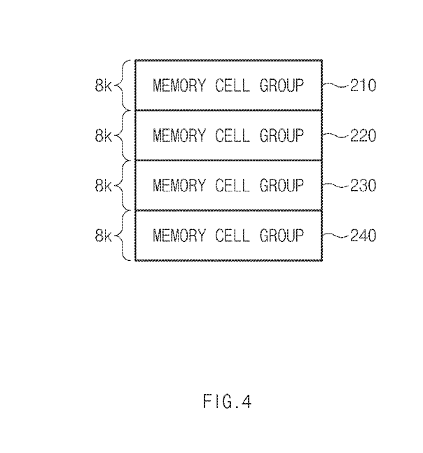

FIG. 4 is a diagram illustrating a representation of an example of a structure of a memory cell according to an embodiment.

The memory cell of FIG. 4 includes a plurality of memory cell groups 210, 220, 230, and 240. For example, the plurality of memory cell groups 210, 220, 230, and 240 may be divided in units of 8 k word lines. In this case, since no sense amplifier is shared among the memory cell groups 210, 220, 230, and 240, even when the active signal is applied to any memory cell group, it may be possible to perform refresh for the other memory cell groups without a risk of a data error.

Referring to FIG. 4, the memory cells are divided in units of 8 k word lines in order to substantially prevent a sense amplifier from being shared, and when no sense amplifier is shared, the memory cells may be divided in other sizes.

FIG. 4 illustrates only that one bank is divided into four groups 210, 220, 230, and 240 having 8 k word lines; however, the present semiconductor device may include a plurality of banks and each bank may be divided into a plurality of memory cell groups (word line groups). In an embodiment, the plurality of memory cell groups may be positioned in substantially the same bank. In an embodiment, the semiconductor memory device may include a plurality of banks, and each bank may include a plurality of memory cell groups (i.e., 210 to 240). In an embodiment, the real active signal RACT is inputted to a memory cell group belonging to any one of the plurality of banks, and the pseudo active signal PACT is inputted to the memory cell group belonging to the any one bank and memory cell groups belonging to other banks. The pseudo active signal PACT inputted to the memory cell group belonging to the any one bank and the pseudo active signal PACT inputted to the memory cell groups belonging to the other banks may substantially be simultaneously inputted.

The memory cell structure of FIG. 4 is a structure for active-precharging all word lines once per a unit time when a refresh command Refresh CMD is inputted from a system.

That is, in the present embodiment, when a command inputted with an arbitrary address is performed, the structure is divided in units of 8 k word lines and then the command is performed. For example, while a read/write operation is being performed for a certain word line, when the word line belongs to the word line group 210, a refresh operation is performed for the other word line groups 220, 230, and 240 except for the word line group 210. In this case, the refresh operation may also be performed only for a part of the other word line groups 220, 230, and 240.

According to the present embodiment, no sense amplifier is shared among memory cell groups, so that it may be possible to simultaneously perform an active operation and a refresh operation without a risk of a data error, resulting in the improvement of memory performance.

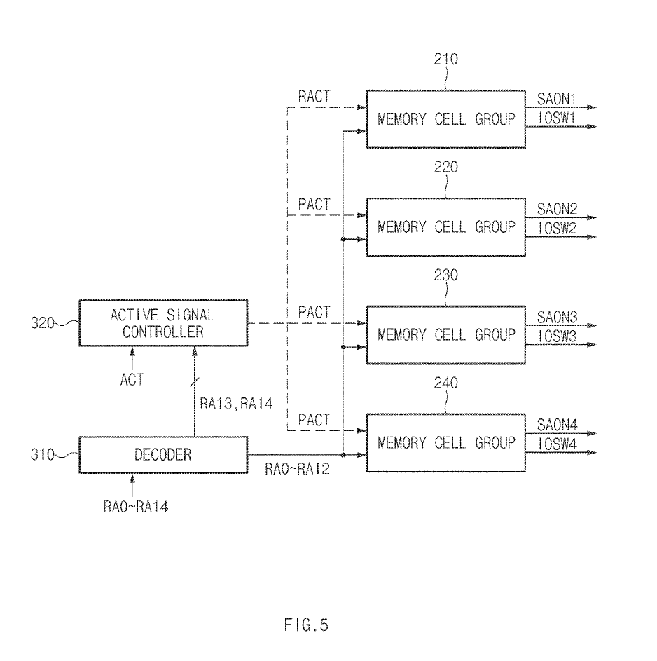

FIG. 5 is a circuit diagram of a representation of an example of a semiconductor device using a memory cell structure of FIG. 4.

A semiconductor device of the present embodiment may include a decoder 310, an active signal controller 320, memory cell groups 210, 220, 230, and 240, wherein each of the memory cell groups 210, 220, 230, and 240, for example, includes 8 k word lines.

The decoder 310 receives an address of a memory cell (hereinafter, referred to as an access target memory cell) to be accessed from an exterior (a system), determines a memory cell group to which the access target memory cell belongs, and transfers the determined memory cell group to the active signal controller 320. Furthermore, the decoder 310 interprets an address (hereinafter, referred to as an in-group address) of the access target memory cell in the memory cell group 210, 220, 230, or 240 including the access target memory cell from the address of the access target memory cell. In an embodiment, the decoder 310 may calculate a plurality of consecutive lower bits or a plurality of consecutive upper bits of the input address (i.e., RA13 to RA14) as the address of the memory cell group in which the active operation is performed in response to the real active signal.

For example, referring to FIG. 4 and FIG. 5, the memory cell has been divided into four groups 210, 220, 230, and 240 (2²=4). Accordingly, as an address (hereinafter, referred to a group address) for distinguishing the groups of the memory cell from one another, 2 bits are required, and upper 2 bits RA13 and RA14 of a plurality of input addresses RA0 to RA14 may be set to indicate the group address. Thus, the decoder 310 extracts the upper 2 bits RA13 and RA14 from the input addresses RA0 to RA14 and determines a memory cell group including the access target memory cell from the extracted values. For example, when the upper 2 bits RA13 and RA14 are “00” in FIG. 3, the decoder 310 determines that the access target memory cell belongs to the memory cell group 210.

The memory cell of FIG. 4 and FIG. 5 has, for example, been divided into four memory cell groups 210, 220, 230, and 240 in units of 8 k word lines (2¹³=8 k). Accordingly, as the in-group address for indicating the 8 k word lines, 13 bits are required. The decoder 310 extracts lower 13 bits RA0 to RA12 from the input addresses RA0 to RA14, decodes the in-group address, and transfers the decoded address to the groups 210, 220, 230, and 240.

Referring to FIG. 4 and FIG. 5, there are four memory cell groups 210, 220, 230, and 240 and each group has 8 k word lines; however, the present embodiment is not limited thereto and the number of memory cell groups and the number of word lines included in each memory cell group may be variously set. For example, when each group includes 8 m word lines, since 2²³=8 m, 23 bits may be used as the in-group address, and when the number of word line groups is 8, since 2³=8, it is possible to determine a group including an access target word line by using 3 bits.

The active signal controller 320 receives the group addresses RA13 and RA14 from the decoder 310 and transmits a real active signal RACT to a memory cell group actually including an access target memory cell while transmitting a pseudo active signal PACT to the other memory cell groups. In an embodiment, the active signal controller generates the real active signal and the pseudo active signal by using one or more consecutive upper bits or lower bits of the input address. Referring to FIG. 3, since the access target memory cell belongs to the memory cell group 210, the active signal controller 320 transmits the real active signal RACT to the memory cell group 210 and transmits the pseudo active signal PACT to the other memory cell groups 220, 230, and 240.

Each of the memory cell groups 210, 220, 230, and 240 performs an operation or refresh based on an inputted command according to the inputted real active signal RACT or pseudo active signal PACT.

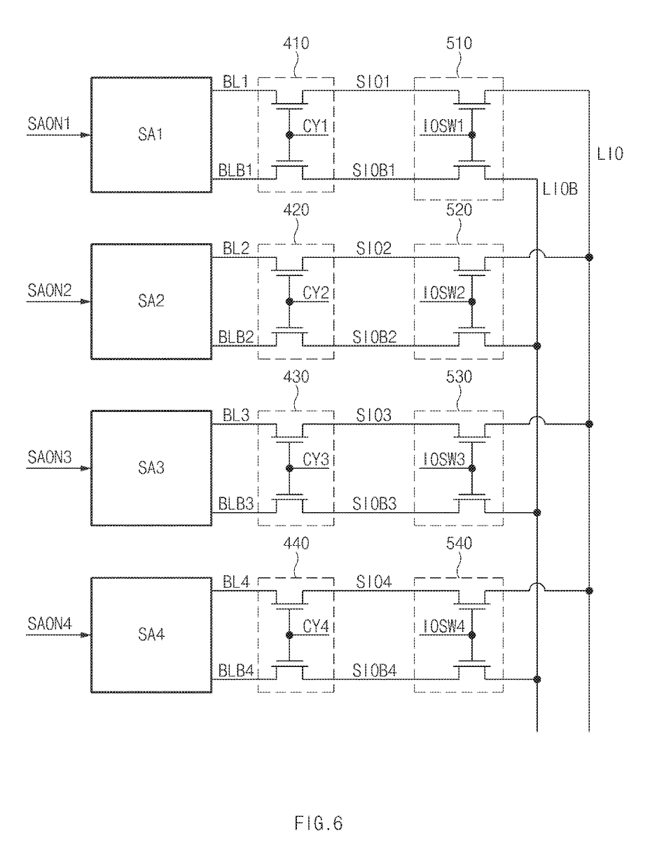

Referring to FIG. 5, for example, when it is assumed that a read command (not illustrated) is inputted, since the real active signal RACT is inputted to the memory cell group 210, a word line corresponding to the in-group addresses RA0 to RA12 inputted from the decoder 310 is activated. Then, in order to output a data value of the activated word line, a sense amplifier enable signal SAON1 for driving a sense amplifier is also enabled. Input/output switch signals IOSW1 to IOSW4 are signals for enabling input/output for memory cells in the memory cell groups, and they will be described later with reference to FIG. 6.

Since the pseudo active signal PACT is inputted to the memory cell groups 220, 230, and 240, a refresh operation is performed for the memory cell groups 220, 230, and 240. In this case, the refresh operation is performed for all word lines corresponding to the other 13 bits RA0 to RA12 except for the upper 2 bits RA13 and RA14 for distinguishing the memory cell groups from one another among the input addresses RA0 to RA12. That is, the refresh is performed for word lines corresponding to the in-group addresses RA0 to RA12 of the memory cell group 220, word lines corresponding to the in-group addresses RA0 to RA12 of the memory cell group 230, and word lines corresponding to the in-group addresses RA0 to RA12 of the memory cell group 240.

In this case, the memory cell groups 220, 230, and 240 output sense amplifier enable signals SAON2 to SAON4 for outputting data values of the activated word lines to sense amplifiers. However, since the input/output switch signals IOSW2 to IOSW4 are signals for enabling input/output for memory cells in the memory cell groups 220, 230, and 240, they are disabled.

Hereinafter, control of the input/output switch signals IOSW1 to IOSW4 will be described with reference to FIG. 6.

FIG. 6 is a circuit diagram of a representation of an example of an input/output terminal of a semiconductor device according to an embodiment.

The semiconductor device of FIG. 6 may include sense amplifiers SA1 to SA4, column selection circuits 410, 420, 430, and 440, and input/output switching circuits 510, 520, 530, and 540.

The sense amplifiers SA1 to SA4 respectively receive the sense amplifier enable signals SAON2 to SAON4 outputted from FIG. 5, thereby amplifying voltages between bit lines BL1 to BL4 and bit line bar lines BLB1 to BLB4.

The column selection circuits 410, 420, 430, and 440 output the voltages amplified by the sense amplifiers SA1 to SA4 to segment input/output lines SIO1 to SI04 and segment input/output bar lines SIOB1 to SIOB4 according to column selection signals CY1 to CY4.

The input/output switching circuits 510, 520, 530, and 540 include input/output switching transistors IOSW1 to IOSW4, respectively. Accordingly, when the input/output switching transistors IOSW1 to IOSW4 are turned on, the input/output switching circuits 510, 520, 530, and 540 output voltages of the segment input/output lines SIO1 to SI04 and segment input/output bar lines SIOB1 to SIOB4 to final output line LIO and final output line bar LIOB.

Hereinafter, the operation of the input/output terminal of the semiconductor device of FIG. 6 having an aforementioned structure will be described.

As the real active signal RACT is inputted to the memory cell group 210 in FIG. 5, when the sense amplifier enable signal SAON1 is enabled, the sense amplifier SA1 amplifies and outputs signals of the bit lines BL1 and BLB1. The amplified signals are outputted to the segment input/output lines SIO1 and SIOB1 when the column selection signal CY1 is enabled.

When only a refresh operation is performed, since a precharge operation should be performed after an active operation, there are no problems. However, in the present embodiment, since refresh is simultaneously performed in a general active operation, it is necessary to control the refresh.

A present embodiment may include a configuration for disabling the other input/output switching transistors IOSW2 to IOSW4 except for the input/output switching transistor IOSW1 corresponding to a memory cell group including an access target memory cell. For example, referring to FIG. 6, in the memory cell group 210 including the access target memory cell, that is, only in a memory cell group receiving the real active signal RACT, the input/output switching transistor IOSW1 is enabled, and in the other memory cell groups 220, 230, and 240, the input/output switching transistors IOSW2 to IOSW4 are disabled. In the present embodiment, by such a configuration, data is outputted from only a cell (a word line) corresponding to an actually inputted address when an active command is inputted.

The present embodiments are not limited thereto.

For example, in the present embodiment, each word line group has been divided into four groups to include 8 k word lines; however, a sense amplifier should be shared among the groups and the present embodiment is not limited thereto.

The case in which the number of banks is 1 has been described; however, when there are a plurality of banks, only a part of the banks may be divided into word line groups or all the banks may be divided into word line groups.

The case in which refresh is performed for each word line group has been described; however, the refresh may be performed for only a part of the word line groups.

Refresh for word line groups may be simultaneously performed, or may be sequentially performed in consideration of current consumption.

The case, in which an in-group address is transmitted to each word line group from the decoder and refresh is performed for a word line corresponding to the in-group address of each word line group, has been described; however, the in-group address may not be transmitted to each word line group from the decoder. Instead, the decoder may include a counter for refreshing all word lines of each memory cell group and each memory cell group may allow a word line corresponding to an output value of the counter to be refreshed, that is, active-precharged.

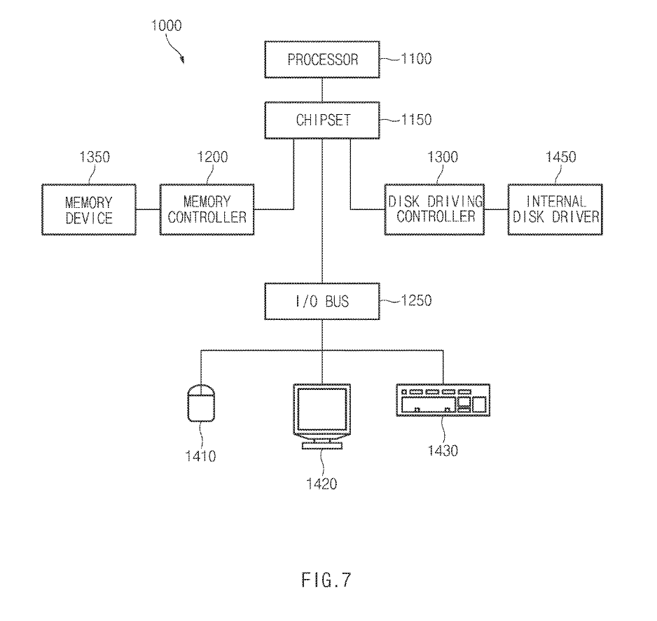

The semiconductor devices as discussed above (see FIGS. 1-6) are particular useful in the design of other memory devices, processors, and computer systems. For example, referring to FIG. 7, a block diagram of a system employing a semiconductor device in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor device as discussed above with reference to FIGS. 1-6. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device as discussed above with relation to FIGS. 1-6, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 7 is merely one example of a semiconductor device as discussed above with relation to FIGS. 1-6. In alternate embodiments, such as, for example but not limited to, cellular phones or digital cameras, the components may differ from the embodiments illustrated in FIG. 7.

While various embodiments have been described above, it will be understood to those skilled in the art that the embodiments described are by way of example only. Accordingly, the semiconductor device described herein should not be limited based on the described embodiments.

1. A semiconductor device comprising:
a plurality of memory cell groups, and
an active signal controller configured to, based on an active signal, generate a real active signal with respect to a memory cell group including an access target memory cell corresponding to an input address and generate a pseudo active signal with respect to one or more of other memory cell groups except for the memory cell group,
wherein, while an active operation is performed in the memory cell group including the access target memory cell in correspondence to the real active signal, a refresh operation is performed in one or more of other memory cell groups in correspondence to the pseudo active signal.

2. The semiconductor device of claim 1, wherein the plurality of memory cell groups are prevented from sharing a sense amplifier.

3. The semiconductor device of claim 1, wherein each of the plurality of memory cell groups is a word line group having a predetermined number of word lines.

4. The semiconductor device of claim 3, wherein the plurality of word line groups include substantially the same number of word lines.

5. The semiconductor device of claim 1, further comprising:
a decoder configured to decode the input address and calculate an address for the memory cell group including the access target memory cell in which the active operation is performed in correspondence to the real active signal.

6. The semiconductor device of claim 5, wherein the decoder calculates a plurality of consecutive lower bits or a plurality of consecutive upper bits of the input address as the address of the memory cell group in which the active operation is performed in correspondence to the real active signal.

7. The semiconductor device of claim 6,
wherein the active signal controller configured to determine the memory cell group including the access target memory cell by using a bit except for the bits of the input address used by the decoder, generate the real active signal with respect to the memory cell group including the access target memory cell, and generate the pseudo active signal with respect to one or more of other memory cell groups except for the memory cell group.

8. The semiconductor device of claim 1,
wherein the active signal controller configured to determine the memory cell group including the access target memory cell from the input address, generate the real active signal with respect to the memory cell group including the access target memory cell, and generate the pseudo active signal with respect to one or more of other memory cell groups except for the memory cell group.

9. The semiconductor device of claim 8, wherein the active signal controller generates the real active signal and the pseudo active signal by using one or more consecutive upper bits or lower bits of the input address.

10. The semiconductor device of claim 1, wherein, when a read or write signal is applied, input and output switching transistors coupled with the memory cell group, in which the active operation is performed, are activated.

11. The semiconductor device of claim 1, wherein input and output switching transistors coupled with one or more of the other memory cell groups, in which the refresh operation is performed, are deactivated.

12. The semiconductor device of claim 1, wherein the plurality of memory cell groups are positioned in substantially the same bank.

13. The semiconductor device of claim 1, wherein the refresh operation is simultaneously performed in two or more of the other memory cell groups in correspondence to pseudo active signals simultaneously inputted to the two or more other memory cell groups.

14. The semiconductor device of claim 1, wherein the refresh operation is sequentially performed in two or more of the other memory cell groups in correspondence to pseudo active signals sequentially inputted to the two or more of the other memory cell groups.

15. The semiconductor device of claim 1, wherein the refresh operation is sequentially performed for all memory cells belonging to one or more of the other memory cell groups.

16. The semiconductor device of claim 1, wherein sense amplifiers of the memory cell group, in which the active operation is performed, and the memory cell group, in which the refresh operation is performed, are activated.

17. The semiconductor device of claim 1, wherein the semiconductor device includes a plurality of banks, and each bank includes a plurality of memory cell groups.

18. The semiconductor device of claim 17, wherein the real active signal is inputted to a memory cell group belonging to any one of the plurality of banks, and the pseudo active signal is inputted to the memory cell group belonging to the any one bank and memory cell groups belonging to other banks.

19. The semiconductor device of claim 18, wherein the pseudo active signal inputted to the memory cell group belonging to the any one bank and the pseudo active signal inputted to the memory cell groups belonging to the other banks are substantially simultaneously inputted.
